(19) United States
(12) Patent Application Publication
(10) Pub. No.: US 2007/0236884 A1
(43) Pub. Date: Oct. 11, 2007

(54) HEAT SINK AND METHOD FOR MANUFACTURING THE SAME

(75) Inventors: Wan-Lin Xia, Shenzhen (CN); Tao Li, Shenzhen (CN); Min-Qi Xiao, Shenzhen (CN)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: FOXCONN TECHNOLOGY CO., LTD., TU CHENG (TW)

(21) Appl. No.: 11/308,556

(22) Filed: Apr. 6, 2006

(51) Int. Cl. H05K 7/20

(52) U.S. Cl. 361/700

(57) ABSTRACT

A heat sink includes a heat pipe having a hollow body with an airtight chamber defined therein, and a quantity of working fluid contained in the chamber. The heat sink further includes a plurality of fins integrally formed with the heat pipe and extending outwards from an outer surface of the body. A skiving is performed to a metal pipe to obtain the hollow body and the fins integrally extending from the hollow body. Accordingly, there is no interface heat resistance between the fins and the hollow body.

### FIELD OF THE INVENTION

The present invention relates to a heat sink, and more particularly to a heat sink comprising a heat pipe integrally formed with a plurality of fins, and to a method for manufacturing the same.

### DESCRIPTION OF RELATED ART

As computer technology continues to advance, electronic components such as central processing units (CPUs) of computers are made to provide faster operational speeds and greater functional capabilities. When a CPU operates at a high speed in a computer enclosure, its temperature usually increases enormously. It is desirable to dissipate the generated heat of the CPU quickly.

Conventionally, a heat sink is used to dissipate the heat generated by a CPU. A conventional heat sink comprises a base contacting with the CPU and a plurality of fins attached to the base. The heat sink dissipates heat by conduction. However, as the heat generated by the CPU and other electronic devices continues increasing, the conventional heat sink can not meet heat dissipating requirements any longer. Thus, heat sinks combined with heat pipes gradually replace the conventional heat sink. A heat pipe has an evacuated cavity and a quantity of working fluid sealed in the cavity. The heat pipe transfers heat by means of phase change of the working fluid. Thus, the heat pipe has good heat conductivity and can quickly transfer heat from one place to another place. In practice, the heat pipes are usually inserted into a plurality of fins to dissipate the heat to surrounding air via the fins.

The connection between the heat pipe and the fins is usually via welding or interference fitting joint; as a result, an interface heat resistance is formed between the heat pipe and the fins, which degrades the heat conduction from the heat pipe to the fins. Furthermore, the high temperature during the welding is possible to damage capillary structure and hermetical effectiveness of the heat pipe. These possible damages can result in that the functional reliability of the heat pipe is weakened and the useful life of the heat pipe is shortened.

### SUMMARY OF INVENTION

A heat sink comprises a heat pipe comprising a hollow body with an airtight chamber defined therein, and a quantity of working fluid contained in the chamber. The heat sink further comprises a plurality of fins integrally formed with the heat pipe and extending outwards from an outer surface of the body. The hollow body has a closed bottom end for contacting with a heat-generating electronic component, and a top end enclosed by a cap. The hollow body is vacuumed. The fins are integrally formed with the heat pipe by skiving the heat pipe, whereby there is substantially no interface heat resistance between the heat pipe and the fins.

Other advantages and novel features will become more apparent from the following detailed description of preferred embodiments when taken in conjunction with the accompanying drawings, in which:

### BRIEF DESCRIPTION OF DRAWINGS

FIG. 1 is an exploded view of a heat sink in accordance with a preferred embodiment of the present invention;

FIG. 2 is an assembled view of FIG. 1;

FIG. 3 is a cross-sectional view taken along a line □-□ of FIG. 2;

FIG. 4 is a top plan view of FIG. 2; and

FIG. 5 is a perspective view of a heat sink in accordance with another preferred embodiment of the present invention.

### DETAILED DESCRIPTION

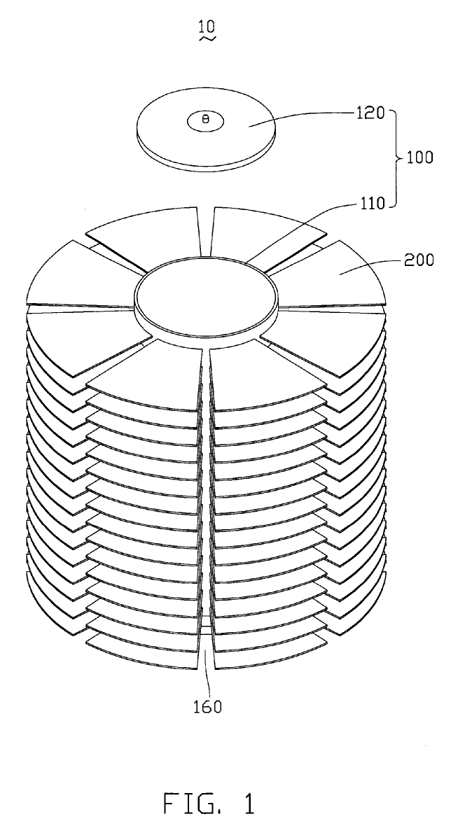

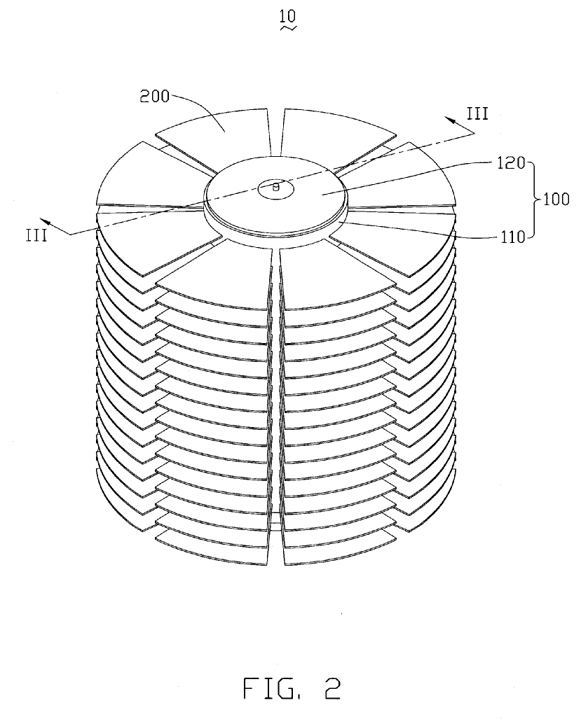

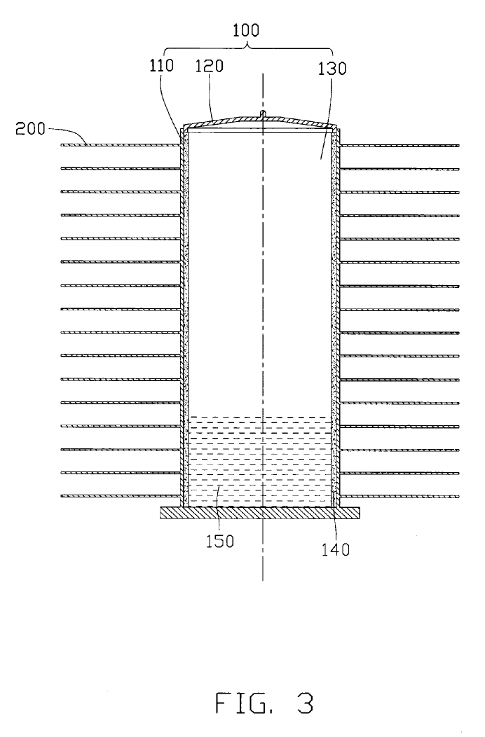

Referring to FIGS. 1-3, a heat sink 10 in accordance with a preferred embodiment of the invention comprises a heat pipe 100 and a plurality of fins 200 radially and outwardly extending form an outer surface of the heat pipe 100.

The heat pipe 100 comprises a hollow body 110 having a circular cross-section. The body 110 has a sealed bottom end, and an opening (not labeled) defined in a top end thereof. A cap 120 covers the opening of the body 110, and seals the opening to form a sealed chamber 130 in the body 110. A capillary structure 140 is arranged on an inner surface of the hollow body 110 and between the bottom end and the cap 120. The chamber 130 contains a quantity of working fluid such as water 150 therein. The quantity of water 150 to be used can be easily determined by those skilled in art of heat pipes.

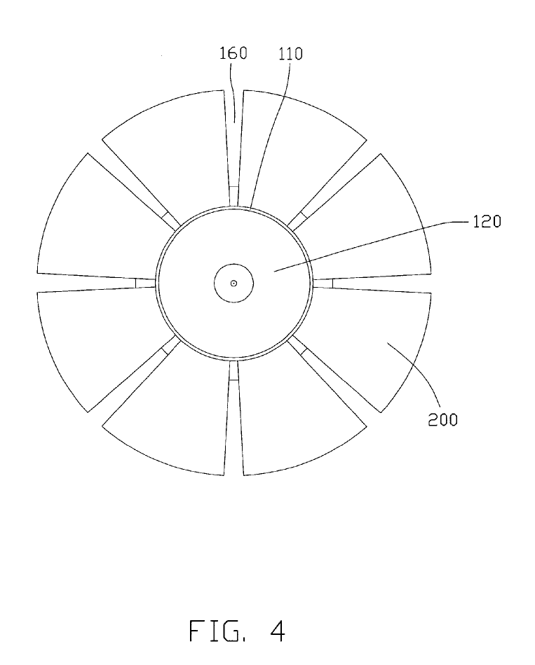

Referring also to FIG. 4, the fins 200 are leaf-like distributed on the outer surface the heat pipe 100, and perpendicular to an axial direction of the body 110 of the heat pipe 100. All of the fins 200 can be divided into eight fin groups at intervals along a circumferential direction of the body 110 of the heat pipe 100; that is, there are eight fins 200 located at a same level of the circumference of the heat pipe 100. Each fin group has a plurality of spaced fins 200 arranged on the circumference of the heat pipe 10 along the axial direction of the body 110 of the heat pipe 100. Thus, a plurality of air-channels 160 is formed between adjacent fin groups and is parallel to the axial direction of the heat pipe 100. It can be understood that the distribution of the fins 200 on the heat pipe 100 can be changed according to practical application; for example, the number of the fins located at the same level of the heat pipe 100 may be two, three, four or other number.

In use of the heat sink 10, the bottom end of the heat pipe 100 is attached to a top surface of an electronic component such as a CPU. The water 150 absorbs heat originated from the CPU, and evaporates into vapor. The vapor flows upwardly through the chamber 130 of the heat pipe 100 toward the cap 120. During the movement of the vapor, the vapor dissipates the heat to the body 110 of the heat pipe 100, and then condenses into water 150 and returns back to the bottom end of the heat pipe 100 for another circulation. The condensed water 150 is driven to flow back by the gravity and the capillary function of the capillary structure 140. The heat transferred to the body 110 of the heat pipe 100 is radiated by the fins 200 to surrounding air. Since the fins 200 are integrally formed with the heat pipe 100, there is substantially no interface heat resistance between the heat pipe 100 and the fins 200. Therefore, the heat accumulated at the body 110 of the heat pipe 100 can be quickly dissipated via the fins 200, which can efficiently utilize the heat pipe 100 to conduct heat form the CPU to the fins 200 to improve the performance of the heat sink 10 of the present invention.

A method for manufacturing the above-described heat sink 10 comprises following steps: (1) offering a hollow copper pipe; (2) performing a skiving operation on an outer circumference of the copper pipe by using a wedge-shaped skiving tool to form the fins 200 whereby the hollow body 110 is also formed; the skiving operation being performed to firstly skive a group of the fins 200 on the circumference of the copper pipe; then the copper pipe is rotated about its longitudinal axis for about 45 degrees, and the skiving operation continuing to form a neighboring group of the fins 200; (3) forming the capillary structure 140 on the inner surface of the body 110, for example, by sintering metal powder onto the inner surface of the body 110; (4) sealing the bottom end of the body 110 and filling the body 110 with a quality of working fluid 150; (5) vacuuming the body 110 via the open top end of the body 110 and sealing the open top end of the body 110 by using the cap 120 thereby to form the heat pipe 100 integrally formed with the plurality of fins 200 to thereby obtain the heat sink 10.

Additionally, the step (3) as described above can be omitted, that is the step (4) goes after the step (2) directly. In this case, the condensed working fluid flows back to the bottom end only by gravity.

The method utilizes the skiving technology to skive out a plurality of fins on the outer surface of the heat pipe 100. The fins 200 and the hollow body 110 of the heat pipe 100 are formed from a one-piece stock; thus, there is no interface heat resistance between the heat pipe 100 and the fins 200. The skiving technology has a fast processing capability and produces fins with a small thickness, which can increase the density of the fins 200 on the outer surface of the heat pipe 100. Furthermore, according to the present invention, the welding operation is omitted, whereby the possible damages to the heat pipe 100 by the high temperature of the welding can be avoided in the present invention. Thus, the functional reliability of the heat pipe 100 can be improved and the useful life of the heat pipe 100 can be extended.

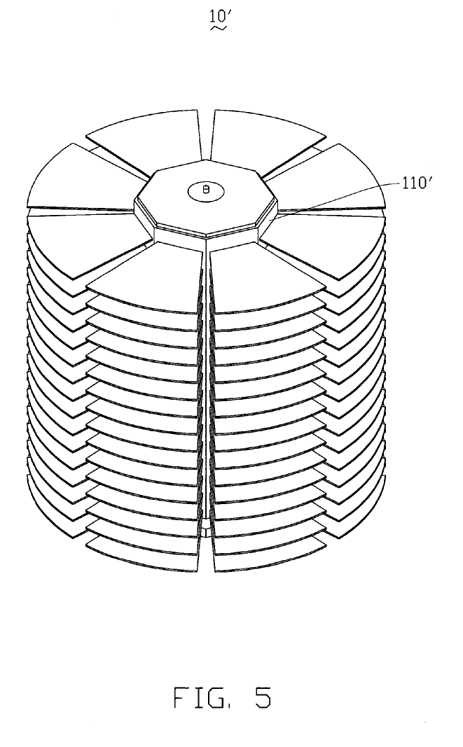

It can be understood that the heat pipe may be a prism having a polygonal cross-section, such as triangular-prism, square prism, octahedron-prism and so on, and the number of the fin groups may be adjusted according to the number of the sides of the cross-section of the heat pipe. FIG. 5 shows another heat sink 10′ with a heat pipe 110′ having an octahedron-prism shape and eight fin groups located at different side surfaces of the heat pipe 110′, respectively.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A heat sink comprising:
a heat pipe comprising a hollow body with an airtight chamber defined therein, and a quantity of working fluid contained in the chamber; and
a plurality of fins integrally formed with the heat pipe and extending outwards from an outer surface of the body, wherein there is substantially no interface heat resistance between the heat pipe and the fins.

2. The heat sink as claimed in claim 1, wherein the fins are divided into a plurality of groups each extending along an axial direction of the body of the heat pipe.

3. The heat sink as claimed in claim 2, wherein the airtight chamber is vacuumed.

4. The heat sink as claimed in claim 1, wherein a capillary structure is formed on an inner surface of the chamber of the heat pipe.

5. The heat sink as claimed in claim 1, wherein the body has a circular cross-section.

6. The heat sink as claimed in claim 5, wherein the body has a polygonal cross-section.

7. The heat sink as claimed in claim 6, wherein the fins are divided into a plurality of fin groups each extending along an axial direction of the body of the heat pipe, and the number of the fin groups is correspondent to a number of sides of the cross-section of the heat pipe.

8. The heat sink as claimed in claim 7, wherein the airtight chamber is vacuumed.

9. A method for manufacturing a heat sink, comprising following steps: (1) offering a hollow metal pipe having an opening at an end thereof, and skiving on an outer circumference of the hollow metal pipe to form a hollow body and a plurality of fins on the hollow body; (2) filling the body with a quality of working fluid; (3) sealing the opening to thereby achieve the heat sink which has a heat pipe and the plurality of fins integrated with the heat pipe.

10. The method as claimed in claim 9, wherein the fins are divided into a plurality of groups each having a row of fins on the outer circumference of the hollow body along an axial direction of the hollow body.

11. The method as claimed in claim 9, further comprising a step between steps (1) and (2): forming a capillary structure on an inner surface of the body.

12. The method as claimed in claim 9, wherein the body has a circular cross-section.

13. The method as claimed in claim 9, wherein the body has a polygonal cross-section.

14. The method as claimed in claim 9, further comprising a step between steps (2) and (3): vacuuming the body.
